(19) United States
(12) Patent Application Publication
(10) Pub. No.: US 2025/0366265 A1
(43) Pub. Date: Nov. 27, 2025

(54) LED DEVICE, LED ARRAY SUBSTRATE, AND METHOD FOR MANUFACTURING LED DEVICE

(71) Applicant: Japan Display Inc., Tokyo (JP)

(72) Inventors: Masanobu IKEDA, Tokyo (JP); Masumi NISHIMURA, Tokyo (JP)

(73) Assignee: Japan Display Inc., Tokyo (JP)

(21) Appl. No.: 19/291,693

(22) Filed: Aug. 6, 2025

Related U.S. Application Data
(63) Continuation of application No. PCT/JP2024/003459, filed on Feb. 2, 2024.

(30) Foreign Application Priority Data
Feb. 28, 2023 (JP) 2023-030143

(51) Int. Cl. H10H 20/825; H01L 25/075; H10H 20/01; H10H 20/815; H10H 20/819; H10H 20/831

(52) U.S. Cl. CPC H10H 20/825; H01L 25/0753; H10H 20/01335; H10H 20/032; H10H 20/815; H10H 20/819; H10H 20/8312

(57) ABSTRACT

An LED device includes an amorphous glass substrate having a first surface and a second surface opposite to the first surface; a buffer layer arranged on the first surface of the amorphous glass substrate; a nitride semiconductor stacked structure including an n-type nitride semiconductor layer, a light-emitting layer, and a p-type nitride semiconductor layer on the buffer layer; a passivation layer covering the nitride semiconductor stacked structure; an n-electrode in contact with the n-type nitride semiconductor layer, and a p-electrode in contact with the p-type nitride semiconductor layer; and a compensation layer on the second surface of the amorphous glass substrate. A coefficient of thermal expansion of the compensation layer exceeds a coefficient of thermal expansion of the amorphous glass substrate and is less than a coefficient of thermal expansion of a semiconductor layer forming the nitride semiconductor stacked structure.

### CROSS-REFERENCE TO RELATED APPLICATIONS

This application is a Continuation of International Patent Application No. PCT/JP2024/003459, filed on Feb. 2, 2024, which claims the benefit of priority to Japanese Patent Application No. 2023-030143, filed on Feb. 28, 2023, the entire contents of which are incorporated herein by reference.

### FIELD

An embodiment of the present invention relates to an LED device including an amorphous glass substrate, an LED array substrate including an LED device region on the amorphous glass substrate, and a method for manufacturing an LED device using the amorphous glass substrate.

### BACKGROUND

A light emitting diode (hereinafter also referred to as “LED” or “LED device”) is manufactured using a gallium nitride semiconductor material. A gallium nitride semiconductor film is formed on a sapphire substrate at a high temperature of 800° C. to 1100° C. by metal organic chemical vapor deposition (MOCVD), hydride vapor phase deposition (HVPE) and the like. To form a large-sized display panel with LED devices, it is necessary to form a gallium nitride semiconductor film on an amorphous glass substrate. However, since the heat-resistant temperature of the amorphous glass substrate is less than 800° C., it is necessary to lower the film deposition temperature, and as a result, there is a problem that a gallium nitride semiconductor film having high quality crystallinity cannot be prepared.

On the other hand, an LED device is disclosed which is formed by forming a silicon oxide film on a glass substrate, forming an amorphous silicon film and an AlₓGa₁₋ₓN buffer layer on the silicon oxide film, and crystal growing a nitride-based compound semiconductor thereon (refer to Japanese laid-open patent publication No. 2000-124140).

It is necessary to perform scribing to separate the LED devices even when a glass substrate is used. As a method for scribing a glass substrate, a laser scribing method or a mechanical scribing method may be applicable. The laser scribing method locally heats the irradiation region of the laser beam. The mechanical scribing method may include scribing lines in the glass using a scribing blade (for example, a scribing wheel).

### SUMMARY

An LED device in an embodiment according to the present invention includes an amorphous glass substrate having a first surface and a second surface opposite to the first surface; a buffer layer arranged on the first surface of the amorphous glass substrate; a nitride semiconductor stacked structure including an n-type nitride semiconductor layer, a light-emitting layer, and a p-type nitride semiconductor layer on the buffer layer; a passivation layer covering the nitride semiconductor stacked structure; an n-electrode in contact with the n-type nitride semiconductor layer, and a p-electrode in contact with the p-type nitride semiconductor layer; and a compensation layer on the second surface of the amorphous glass substrate. A coefficient of thermal expansion of the compensation layer exceeds a coefficient of thermal expansion of the amorphous glass substrate and is less than a coefficient of thermal expansion of a semiconductor layer forming the nitride semiconductor stacked structure. An end of the buffer layer and an end of the nitride semiconductor stacked structure is inside an end of the amorphous glass substrate. The passivation layer extends from the end of the buffer layer and the nitride semiconductor stacked structure to above the first surface of the amorphous glass substrate.

A method for manufacturing LED device in an embodiment according to the present invention includes forming a compensation layer on an amorphous glass substrate, the amorphous glass substrate having a first surface and a second surface opposite the first surface, and the compensation layer being formed on the second surface; forming a buffer layer on the first surface of the amorphous glass substrate; forming a nitride semiconductor stack on the buffer layer, the nitride semiconductor stack including an n-type nitride semiconductor layer, a light-emitting layer, and a p-type nitride semiconductor layer; patterning the nitride semiconductor stack and the buffer layer, forming LED device regions and a scribe region between the LED device regions; forming a passivation layer covering the LED device regions and the scribe region; forming openings in the passivation layer overlapping the LED device regions; forming electrodes overlapping the openings; forming an organic sealing layer on the passivation layer and the electrodes covering the LED device regions; attaching a protective film to the first surface of the amorphous glass substrate; forming an opening region in the compensation layer, the opening region being formed in the region overlapping the scribe region; and individualizing the LED device regions at the scribe region after removing the protective film.

An LED device substrate in an embodiment according to the present invention includes an amorphous glass substrate having a first surface and a second surface opposite to the first surface; LED device regions arranged in a space separated from the first surface of the amorphous glass substrate; a scribe region arranged on the first surface in a region separated from the LED device regions; a passivation layer covering the LED device regions and the scribe region on the first surface; and a compensation layer on the second surface of the amorphous glass substrate. The LED device region includes a buffer layer on the first surface of the amorphous glass substrate, and a nitride semiconductor stack including an n-type nitride semiconductor layer, a light-emitting layer, and a p-type nitride semiconductor layer, and n-electrodes and a p-electrodes. A thermal expansion coefficient of the compensation layer is greater than a thermal expansion coefficient of the amorphous glass substrate and less than a thermal expansion coefficient of semiconductor layers forming the nitride semiconductor stack. The passivation layer extends to the scribe region. The buffer layer, the nitride semiconductor stack, the n-electrode and the p-electrode does not extend into the scribe region. The compensation layer includes an opening region overlapping the LED device regions and partially not overlapping the scribe region.

### BRIEF DESCRIPTION OF DRAWINGS

FIG. 1A is a plan view of an LED array substrate according to an embodiment of the present invention.

FIG. 1B is a plan view of LED device regions formed on an LED array substrate according to an embodiment of the present invention.

FIG. 2A is a cross-sectional view of an LED array substrate corresponding to line A1-A2 shown in FIG. 1B.

FIG. 2B is a cross-sectional view of an LED device according to an embodiment of the present invention.

FIG. 3A is a flowchart illustrating a method for manufacturing an LED array substrate according to an embodiment of the present invention.

FIG. 3B is a flowchart illustrating a method for manufacturing an LED array substrate according to an embodiment of the present invention.

FIG. 4A is a cross-sectional view illustrating a method for manufacturing an LED array substrate according to an embodiment of the present invention.

FIG. 4B is a cross-sectional view illustrating a method for manufacturing an LED array substrate according to an embodiment of the present invention.

FIG. 4C is a cross-sectional view illustrating a method for manufacturing an LED array substrate according to an embodiment of the present invention.

FIG. 4D is a cross-sectional view illustrating a method for manufacturing an LED array substrate according to an embodiment of the present invention.

FIG. 4E is a cross-sectional view illustrating a method for manufacturing an LED array substrate according to an embodiment of the present invention.

FIG. 4F is a cross-sectional view illustrating a method for manufacturing an LED array substrate according to an embodiment of the present invention.

FIG. 5A is a cross-sectional view illustrating a method for manufacturing an LED array substrate according to an embodiment of the present invention.

FIG. 5B is a cross-sectional view illustrating a method for manufacturing an LED array substrate according to an embodiment of the present invention.

FIG. 5C is a cross-sectional view illustrating a method for manufacturing an LED array substrate according to an embodiment of the present invention.

FIG. 5D is a cross-sectional view illustrating a method for manufacturing an LED array substrate according to an embodiment of the present invention.

FIG. 6A is a cross-sectional view illustrating a method for manufacturing an LED array substrate according to an embodiment of the present invention.

FIG. 6B is a cross-sectional view illustrating a method for manufacturing an LED array substrate according to an embodiment of the present invention.

FIG. 7A is a plan view of an LED device region formed on an LED array substrate according to an embodiment of the present invention.

FIG. 7B is a cross-sectional view of an LED array substrate corresponding to the line B1-B2 shown in FIG. 7A.

FIG. 8A is a plan view of an LED array substrate according to an embodiment of the present invention.

FIG. 8B is a plan view of a circular substrate scribed from an LED array substrate according to an embodiment of the present invention.

### DESCRIPTION OF EMBODIMENTS

Hereinafter, embodiments of the present invention are described with reference to the drawings. However, the present invention can be implemented in many different aspects and should not be construed as being limited to the description of the following embodiments. For the sake of clarifying the explanation, the drawings may be expressed schematically with respect to the width, thickness, shape, and the like of each part compared to the actual aspect, but this is only an example and does not limit the interpretation of the present invention. For this specification and each drawing, elements similar to those described previously with respect to previous drawings may be given the same reference sign (or a number followed by A, B, or a, b, etc.) and a detailed description may be omitted as appropriate. The terms “first” and “second” appended to each element are a convenience sign used to distinguish them and have no further meaning except as otherwise explained.

In the embodiments described below, an LED array substrate refers to a substrate where a plurality of LED devices is arrayed on an amorphous glass substrate before being individualized.

### First Embodiment

The present embodiment describes the structure of an LED array substrate and an LED device individualized from the LED array substrate.

### 1-1. LED Array Substrate

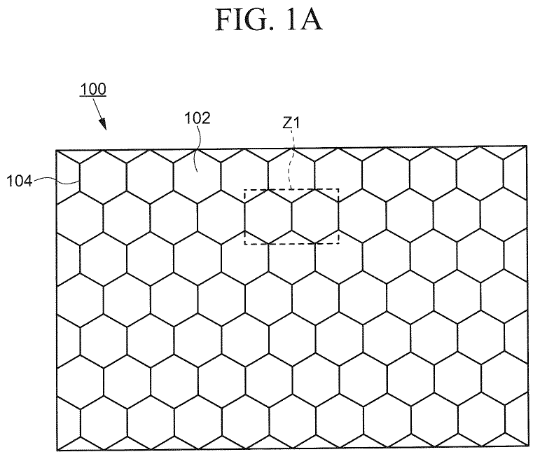

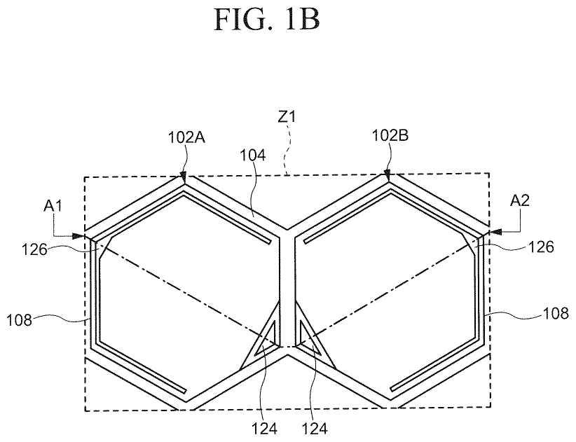

FIG. 1A shows a plan view of an LED array substrate 100 according to the present embodiment. The LED array substrate 100 includes a plurality of LED device regions 102 arranged on an amorphous glass substrate and a scribe region 104 surrounding the plurality of LED device regions 102.

The plurality of LED device regions 102 are regions where LED devices are individualized, and the scribe region 104 is a region where scribing (also called “breaking”) is performed to individualize the LED devices. The plurality of LED device regions 102 is a region where a plurality of layers including a nitride semiconductor layer forming an LED device are disposed, and the scribe region 104 is a region which does not include a nitride semiconductor layer.

As shown in FIG. 1A, the plurality of LED device regions 102 have a polygonal shape in a plan view. FIG. 1A illustrates an exemplary case where the plurality of LED device regions 102 are hexagonal. The outline of an LED device formed using a sapphire substrate or the like in a plan view is usually square in order to facilitate scribing. On the other hand, the plurality of LED device regions 102 of the present embodiment can be formed not only in a rectangular shape but also in a polygonal shape having a larger number of angles than a rectangular shape.

FIG. 1B is an enlarged view of the region Z1 shown in FIG. 1A and shows a plan view of the first LED device region 102A and the second LED device region 102B. The first LED device region 102A and the second LED device region 102B are arranged adjacent to each other. The scribe region 104 is arranged between the first LED device region 102A and the second LED device region 102B.

The first LED device region 102A includes a buffer layer 112 (not shown), a nitride semiconductor stack 108, an n-electrode 124, and a p-electrode 126. The second LED device region 102B similarly includes a buffer layer 112 (not shown), a nitride semiconductor stack 108, the n-electrode 124, and the p-electrode 126. The n-electrode 124 is an electrode for forming a contact with the n-type nitride semiconductor layer included the nitride semiconductor stack 108, and the p-electrode is an electrode for forming a contact with the p-type nitride semiconductor layer included the nitride semiconductor stack 108.

The sizes of the first LED device region 102A and the second LED device region 102B can be appropriately adjusted, and can be applied, for example, from a micro-LED having a diagonal length of 100 μm or less to a large LED having a diagonal length of several tens of millimeters or more. The shapes of the n-electrode 124 and the p-electrode 126 are not limited to the shapes shown in the figure and can be appropriately changed in accordance with the shape and size of the LED device.

The width of the scribe region 104 can be changed in accordance with the scribe system. As the scribing method, for example, laser scribing and mechanical scribing can be applied. Since a laser beam is focused by an optical system and irradiated on the substrate in laser scribing, the width of the scribe region 104 can be about 50 μm to 100 μm. The width of the scribe region 104 is preferably about 150 μm to 300 μm, since the scribe lines are formed by directly abutting the blade against the substrate in mechanical scribing.

As will be described in detail below, the LED device regions 102 and the scribe region 104 differ in the lamination structure of the thin films on the amorphous glass substrate, so that the LED device region 102 can be easily divided into individual pieces even if the LED device region 102 has a non-rectangular shape.

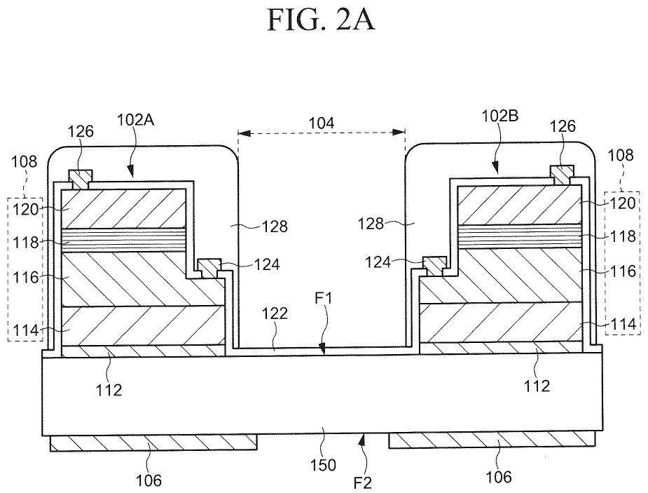

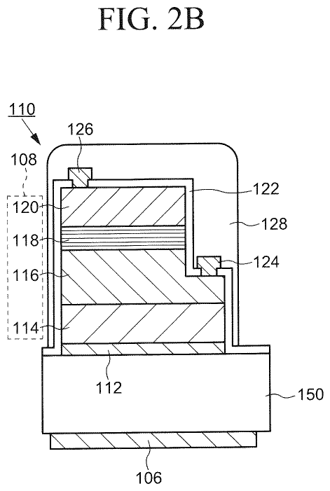

FIG. 2A is a partial cross-sectional view of the LED array substrate 100, and shows a cross-sectional view along the line A1-A2 shown in FIG. 1B.

An amorphous glass substrate 150 is used as a substrate of the LED array substrate 100. The amorphous glass substrate 150 is a thin plate-like substrate having a thickness of about 0.3 mm to 1 mm and has a first surface F1 and a second surface F2 opposite to the first surface F1. As shown in FIG. 2A, the first LED device region 102A and the second LED device region 102B are arranged on the first surface F1 of the amorphous glass substrate 150. The first LED device region 102A and the second LED device region 102B are arranged apart from each other, and the scribe region 104 is arranged between them.

The first LED device region 102A and the second LED device region 102B have a structure where the buffer layer 112 and the nitride semiconductor stack 108 are laminated from the amorphous glass substrate 150 side. The nitride semiconductor stack 108 includes a stacked structure of an undoped nitride semiconductor layer 114, an n-type nitride semiconductor layer 116, a light-emitting layer 118, and a p-type nitride semiconductor layer 120. The scribe region 104 is a region where the buffer layer 112 and the nitride semiconductor stack 108 are removed.

A passivation layer 122 covering the upper surface of the nitride semiconductor stack 108 and the side surfaces of the nitride semiconductor stack 108 and the buffer layer 112 is arranged on the first surface F1 of the amorphous glass substrate 150. The passivation layer 122 extends from the first LED device region 102A and the second LED device region 102B to the scribe region 104. The n-electrode 124 contacts the n-type nitride semiconductor layer 116, and the p-electrode 126 contacts the p-type nitride semiconductor layer 120 through an opening in the passivation layer 122. An organic sealing layer 128 covering the first LED device region 102A and the second LED device region 102B is further arranged on the first surface F1 of the amorphous glass substrate 150. The organic sealing layer 128 is arranged to expose the scribe region 104.

A compensation layer 106 is arranged on the second surface F2 of the amorphous glass substrate 150. The compensation layer 106 is arranged in a region overlapping the first LED device region 102A and the second LED device region 102B, and an opening region of the compensation layer 106 is arranged in a region overlapping the scribe region 104. Each configuration of the LED array substrate 100 will be described in detail below.

### 1-2-1. Amorphous Glass Substrate

The amorphous glass substrate 150 is typically non-crystalline but may contain regions with some crystalline structure. The upper limit of the coefficient of thermal expansion of the amorphous glass substrate 150 is less than 4.2×10⁻⁶/K, preferably less than 4.0×10⁻⁶/K. The lower limit of the coefficient of thermal expansion of the amorphous glass substrate 150 is greater than 3.0×10⁻⁶/K, and preferably greater than 3.5×10⁻⁶/K. The process temperature (maximum processing temperature) of the LED array substrate 100 is less than 650° C. Therefore, the heat resistance of the amorphous glass substrate 150 is preferably at least 650° C.

The lower limit of the glass transition point of the amorphous glass substrate 150 is 650° C. or more, and preferably 720° C. or more. The upper limit of the glass transition point of the amorphous glass substrate 150 is 900° C. or less, and preferably 810° C. or less. For the same reason, the lower limit of the softening point of the amorphous glass substrate 150 is 900° C. or more, and preferably 950° C. or more. The upper limit of the softening point of the amorphous glass substrate 150 is 1150° C. or less, and preferably 1050° C. or less.

The amorphous glass substrate 150 preferably has a small content of alkali metal components to prevent metal contamination of the nitride semiconductor stack 108. For example, the alkali metal content of the amorphous glass substrate 150 is preferably 0.1 mass % or less.

As the material of the amorphous glass substrate 150, for example, an amorphous glass material formed of aluminoborosilicate glass or aluminosilicate glass is used. The amorphous glass substrate 150 is used in liquid crystal displays and organic electroluminescence displays, and a large area glass substrate called mother glass is available on the market. Using a universal amorphous glass substrate allows the LED device 110 to be larger and adaptable to various shapes, increasing the number of individual devices produced per substrate and improving productivity.

There is no limit to the thickness of the amorphous glass substrate 150, however, it is preferable that the thickness be sufficiently greater than that of the nitride semiconductor stack 108 to reduce warping. For example, the amorphous glass substrate 150 is preferably at least 50 times as thick as the nitride semiconductor stack 108. The amorphous glass substrate 150 preferably has a thickness of, for example, 0.5 mm to 1.0 mm.

Although not shown in figure, a base layer may be arranged on the first surface F1 of the amorphous glass substrate 150 to prevent the diffusion of impurities (for example, moisture or sodium (Na)). The base layer is preferably formed of an inorganic insulating material such as silicon oxide or silicon nitride.

### 1-2-2. Compensation Layer

The compensation layer 106 is arranged on the second surface F2 of the amorphous glass substrate 150. When the LED device is individualized from the LED array substrate 100, it is arranged in a region overlapping the first LED device region 102A and the second LED device region 102B and removed in a region overlapping the scribe region 104. The compensation layer 106 can mitigate the warpage of the amorphous glass substrate 150 due to the difference in the coefficient of thermal expansion between the amorphous glass substrate 150 and the respective layers forming the nitride semiconductor stack 108 because the coefficient of thermal expansion has a predetermined range. The thermal expansion coefficient of the compensation layer is preferably greater than the thermal expansion coefficient of the amorphous glass substrate 150 and less than the thermal expansion coefficient of each layer (undoped nitride semiconductor layer 114, n-type nitride semiconductor layer 116, light-emitting layer 118, p-type nitride semiconductor layer 120) of the nitride semiconductor stack 108.

The lower limit of the thermal expansion coefficient of the compensation layer 106 is, for example, greater than 4.0×10⁻⁶/K, and preferably greater than 4.1×10⁻⁶/K. The upper limit of the thermal expansion coefficient of the compensation layer 106 is, for example, less than 5.0×10⁻⁶/K, and preferably less than 4.6×10 6/K. However, the upper limit and the lower limit of the thermal expansion coefficient of the compensation layer 106 are not limited thereto. It is possible to conduct heat evenly throughout the amorphous glass substrate 150 in the step of forming the nitride semiconductor stack 108, and to achieve uniformity of in-plane characteristics, by setting the thermal conductivity of the compensation layer 106 to a predetermined range. The thermal conductivity of the compensation layer 106 can be suitably adjusted depending on the material constituting the amorphous glass substrate 150, for example, more than 10 W/m K, and preferably more than 40 W/m K.

The thermal conductivity of the compensation layer 106 can be adjusted by the film density. The relationship between the film density and the thermal conductivity differs depending on the material constituting the compensation layer 106. The lower limit of the film density of the compensation layer 106 is, for example, 2.50 g/cm³ or more, and preferably 2.60 g/cm³ or more. The upper limit of the film density of the compensation layer 106 is 4.10 g/cm³ or less, and preferably 4.00 g/cm³ or less.

The material for forming the compensation layer 106 is not particularly limited as long as it satisfies the above-described physical properties. For example, the compensation layer 106 may be formed of an aluminum nitride film or an aluminum oxide film. The compensation layer 106 can be formed by laminating an aluminum nitride film and an aluminum oxide film.

The thickness of the compensation layer 106 is not limited and can be appropriately adjusted from the viewpoint of preventing the amorphous glass substrate 150 from warping. The compensation layer 106 is preferably not excessively thinner than the thickness of the nitride semiconductor stack 108. For example, the compensation layer 106 may have a thickness of 80% or more with respect to the thickness of the nitride semiconductor stack 108.

### 1-2-3. Buffer Layer

The buffer layer 112 is arranged on the first surface of the amorphous glass substrate 150. The buffer layer 112 is arranged to improve the crystal orientation of the nitride semiconductor film formed on the amorphous glass substrate 150. In other words, the buffer layer 112 is arranged so that the c-axis of the nitride semiconductor film grows in the film thickness direction. The nitride semiconductor having a hexagonal close-packed structure is grown in the c-axis direction to minimize the surface energy. Even if a nitride semiconductor film is directly deposited on the amorphous glass substrate 150, there is an effect of lattice mismatch, and the nitride semiconductor film does not grow crystals and does not have c-axis orientation. To accelerate crystallization of the nitride semiconductor film, the buffer layer 112 is arranged on the amorphous glass substrate 150. The buffer layer 112 is preferably c-axis oriented.

The buffer layer 112 is formed of a thin film having a hexagonal close-packed structure, a face-centered cubic structure, or a structure equivalent thereto. Here, the structure equivalent to the hexagonal close-packed structure or the face-centered cubic structure refers to a crystal structure in which the c-axis is not 90° with respect to the a-axis and the b-axis. Since the buffer layer 112 has such a structure, crystal growth in the c-axis direction of the nitride semiconductor film is promoted, and crystallinity can be improved.

The buffer layer 112 is formed of, for example, an insulating material. The insulating material which can be used for forming the buffer layer 112 includes, for example, aluminum nitride (AlN), aluminum oxide (AlxOy), lithium niobate (LiNbO), BiLaTiO, SrFeO, BiFeO, BaFeO, ZnFeO, PMnN-PZT, or biological apatite (BAp) can be used. The buffer layer 112 can be formed by a sputtering method or a vapor deposition method.

The buffer layer 112 may be formed of a conductive material. The buffer layer 112 may be, for example, a conductive material such as titanium (Ti), titanium nitride (TiN), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), or thorium (Th). The buffer layer 112 may consist of silicon (Si), germanium (Ge), or their alloys.

The buffer layer 112 may be a single layer formed of an insulating material, or a conductive material (or a semiconductor material) as described above, or may have a structure where a plurality of layers is laminated. For example, the buffer layer 112 may include a first layer formed of a conductive material and a second layer formed of an insulating material thereon from the amorphous glass substrate 150 side.

The crystallinity of the nitride semiconductor film is affected not only by the crystallinity of the substrate but also by the unevenness of the substrate surface. Therefore, the buffer layer 112 preferably has a smooth surface with little unevenness. For example, the arithmetic means roughness (Ra) of the surface of the buffer layer 112 is preferably less than 2.3 nm. The root means square roughness (Rq) of the surface of the buffer layer 112 is preferably smaller than 2.9 nm. When the roughness of the buffer layer 112 is within this range, the crystallinity of the nitride semiconductor film can be enhanced. To enhance the flatness of the surface, the thickness of the buffer layer 112 is preferably 50 nm or more.

### 1-2-4. Nitride Semiconductor Stack

The nitride semiconductor stack 108 includes an undoped nitride semiconductor layer 114, an n-type nitride semiconductor layer 116, a light-emitting layer 118, and a p-type nitride semiconductor layer 120. The following describes the details of each layer.

### 1-2-4-1. Undoped Nitride Semiconductor Layer

To reduce crystal dislocations of the n-type nitride semiconductor layer 116, the undoped nitride semiconductor layer 114 is arranged on the buffer layer 112. The undoped nitride semiconductor layer 114 is formed using the same semiconductor material as the n-type nitride semiconductor layer 116. For example, the undoped nitride semiconductor layer is formed of gallium nitride. The undoped nitride semiconductor layer 114 is intended to contain no impurity elements for the purpose of valence electron control, and may contain impurity elements such as oxygen, carbon, and hydrogen that are unavoidably included. The thickness of the undoped nitride semiconductor layer 114 is not particularly limited.

### 1-2-4-2. N-Type Nitride Semiconductor Layer

The n-type nitride semiconductor layer 116 is formed by doping impurities, such as silicon (Si) or germanium (Ge), into the nitride semiconductor film to achieve n-type conductivity. That is, the n-type nitride semiconductor layer 116 is an n-type nitride semiconductor film containing silicon or germanium added to a nitride semiconductor film. For example, as the n-type nitride semiconductor layer 116, a gallium nitride film containing silicon or germanium is used. There is no limitation on the film thickness of the n-type nitride semiconductor layer 116, but it is preferable that the film thickness be 50 nm or more and less than 3000 nm.

### 1-2-4-3. Light-Emitting Layer

The light-emitting layer 118 is a region that emits light by recombining electrons transported from the n-type nitride semiconductor layer 116 and holes transported from the p-type nitride semiconductor layer 120. The light-emitting layer 118 has a multi-quantum well (MQW) structure.

### 1-2-4-4. P-Type Nitride Semiconductor Layer

The p-type nitride semiconductor layer 120 is doped with impurities such as magnesium (Mg) to impart p-type conductivity to a nitride semiconductor film. That is, a p-type nitride semiconductor film doped with magnesium is used as the p-type nitride semiconductor layer 120. For example, a gallium nitride film containing magnesium is used as the p-type nitride semiconductor layer 120. Additionally, zinc (Zn) may be used as the impurity in the p-type nitride semiconductor layer 120. There are no restrictions on the film thickness of the p-type nitride semiconductor layer 120, but a film thickness of 50 nm or more and less than 500 nm is preferred.

### 1-2-5. Passivation Layer

The passivation layer 122 is formed by an oxide silicon film, a nitride silicon film, or an aluminum oxide. The passivation layer 122 may have a structure laminated with an oxide silicon film and a nitride silicon film. The passivation layer 122 is arranged to cover the nitride semiconductor stack 108.

### 1-2-6. N-Electrode and P-Electrode

The n-electrode 124 and p-electrode 126 are arranged on the passivation layer 122 and form contacts with the n-type nitride semiconductor layer 116 and p-type nitride semiconductor layer 120, respectively, through the contact holes. The n-electrode 124 is formed of a metal material. When the work function of the n-type nitride semiconductor layer 116 is 3 eV to 4 eV, materials with a work function of 4.5 eV or higher, such as nickel (Ni), gold (Au), platinum (Pt), silver (Ag), or p-type silicon, are selected as the n-electrode 124. The n-electrode 124 may have a metal layer such as aluminum (Al) laminated on top of these metal layers.

The n-electrode 124 is formed, for example, of copper (Cu) and a barrier metal that prevents the diffusion of copper (Cu). Titanium (Ti), titanium nitride (TiN), tantalum (Ta), or tantalum nitride (TaN) may be used as the barrier metal. The n-electrode 124 is, for example, a structure having a layered configuration of titanium (Ti), titanium nitride (TiN), and copper (Cu) in that order.

The p-electrode 126 is formed from metallic materials such as gold (Au), a titanium (Ti)-gold (Au) alloy, nickel (Ni), or transparent conductive films such as indium tin oxide (ITO). Metal materials with a work function of less than 4.5 eV, such as aluminum (Al) or titanium (Ti), are selected for the P-electrode 126. Although not shown, the p-electrode 126 may be formed on the upper surface of the p-type nitride semiconductor layer 120 using conductive metal oxide materials such as indium oxide (In₂O₃), zinc oxide (ZnO), or indium tin oxide (ITO).

### 1-2-7. Organic Sealing Layer

The organic sealing layer 128 is formed from an epoxy-based organic resin material or an acrylic-based organic resin material. The organic sealing layer 128 is preferably formed using an organic resin composition having photosensitivity to selectively form the organic sealing layer 128 so that it covers the LED device regions 102 and exposes the scribe region. It is preferable to use an organic resin material that is transparent to light emitted from the light-emitting layer 118.

### 1-3. Scribe Region

As shown in FIG. 2A, the compensation layer 106 overlapping the scribe region 104 is removed from the second surface F2 of the amorphous glass substrate 150. As described in Section 1-2-2, the compensation layer 106 is formed of an aluminum nitride film, an aluminum oxide film, or the like having high thermal conductivity. The thermal conductivity of aluminum nitride is 285 W/m K, and that of aluminum oxide is 45.5 W/m K. The amorphous glass substrate 150 formed from alkali-free glass has a thermal conductivity of about 1.5 to 1.6 W/m K, indicating that the compensation layer 106 has much higher thermal conductivity.

When dividing the LED array substrate 100 by laser scribing, if the compensation layer 106 with high thermal conductivity is arranged in the scribe region 104, it becomes difficult to localize heating because the thermal energy is dissipated to the surrounding region even when a laser beam is irradiated. To resolve this problem, the LED array substrate 100 has a structure where the compensation layer 106 does not extend into the scribe region 104. That is, when the LED devices 110 are individualized by laser scribing, the compensation layer is not arranged in the scribe region 104, enabling localized heating by the laser beam and allowing good scribing to be performed.

The aluminum nitride and aluminum oxide used as the compensation layer 106 have the characteristics of high Young's modulus and hardness. The Young's modulus of aluminum nitride is 320 GPa, and that of aluminum oxide is 330 GPa. On the other hand, the Young's modulus of the amorphous glass substrate 150 formed from alkali-free glass is reported to be 77 to 83 GPa. When such a hard film is presented in the scribe region 104, it becomes difficult to form scribe lines during mechanical scribing. However, the LED array substrate 100 has a structure where the compensation layer 106 does not extend into the scribe region 104, enabling the formation of scribe lines during mechanical scribing and achieving good scribing performance.

The first surface F1 of the amorphous glass substrate 150 is covered with a passivation layer 122, which has a structure that does not affect scribing in terms of thermal conductivity and Young's modulus (hardness). The thermal conductivity of the silicon oxide and silicon nitride forming the passivation layer 122 is 1.2 W/m K, which is equivalent to the thermal conductivity of the amorphous glass substrate 150. The Young's modulus of silicon oxide is 73 GPa, and that of silicon nitride is 150 GPa, both of which are sufficiently smaller than that of the compensation layer 106. Therefore, even if the passivation layer 122 extends from the LED device regions 102 to the scribe region 104, it does not affect the scribing.

As shown in FIG. 2A, the organic sealing layer 128 does not extend into the center of the scribe region 104. The thermal conductivity of the acrylic resin used to form the organic sealing layer 128 is 70 W/m K, and that of the epoxy resin is 60 W/m K, which is sufficiently low in terms of thermal conductivity. However, when these organic resin materials are heated to high temperatures by a laser beam, a degraded layer forms, causing the conductivity to increase.

The Young's modulus of acrylic resin is 5 GPa, and that of epoxy resin is 7 GPa, so it can be considered sufficiently soft in terms of hardness. However, if the Young's modulus is too low, organic resin material may adhere to the blade during mechanical scribing, requiring frequent maintenance to remove it, which reduces productivity. In contrast, the LED array substrate 100 has a structure where the organic sealing layer 128 does not extend into the scribe region 104, allowing scribe lines to be drawn during mechanical scribing and enabling good scribing results.

In this way, since the LED array substrate 100 according to the present embodiment has a structure in which the LED device regions 102 and the scribe region 104 are distinguished and the compensation layer 106 does not extend to the scribe region 104, either of the laser scribe and the mechanical scribe systems can be applied, and good scribing can be performed.

Since the LED array substrate 100 according to the present embodiment uses the amorphous glass substrate 150, it is possible to increase the area and increase the number of LED devices that can be individualized from a single substrate. The LED array substrate 100 can accommodate large-area formation, enabling the provision of LED devices of various shapes when viewed in a plan view. That is, it can provide LED devices with irregular shapes.

### Second Embodiment

The present embodiment describes an LED device 110 that is individualized from the LED array substrate 100 shown in the first embodiment.

FIG. 2B is a cross-sectional view of an LED device 110 that is individualized from the LED array substrate. The LED device 110 includes a buffer layer 112 arranged on the first surface F1 of the amorphous glass substrate 150, a nitride semiconductor stack 108 arranged on the buffer layer 112, a passivation layer 122, a n-electrode 124 and a p-electrode 126. The LED device 110 includes a compensation layer 106 arranged on the second surface F2 of the amorphous glass substrate 150. The compensation layer 106 is arranged in a region overlapping the buffer layer 112 and the nitride semiconductor stack 108.

The LED device 110 has a structure where the peripheral edges of the buffer layer 112 and the nitride semiconductor stack 108 are arranged inwardly from the edges of the amorphous glass substrate 150. On the other hand, the passivation layer 122 covers the buffer layer 112 and the nitride semiconductor stack 108 and extends from the peripheral edges thereof onto the first surface F1 of the amorphous glass substrate 150 to reach the edges or near the edges thereof. The end of the compensation layer 106 is aligned with or arranged outside the end of the buffer layer 112 and the nitride semiconductor stack 108. However, the end of the compensation layer 106 is arranged further inwards than the end of the amorphous glass substrate 150. In other words, the end of the compensation layer 106 is arranged in the region between the end of the buffer layer 112 and the end of the nitride semiconductor stack 108 and the end of the amorphous glass substrate 150. The ends of the buffer layer 112 and the nitride semiconductor stack 108 need not coincide, and the ends of the buffer layer 112 may be located further outwards than the ends of the nitride semiconductor stack 108.

The shape of the LED device 110 in a plan view may be a square, or it may be a polygonal shape having more angles than a square as shown in FIG. 1A. The shape of the LED device 110 in a plan view may be hexagonal, for example, as shown in FIG. 1B.

According to the LED device 110 of the present embodiment, the passivation layer 122 extends continuously from the LED device region 102 to the first surface F1 of the amorphous glass substrate 150, thereby preventing moisture from penetrating from the boundary between the buffer layer 112 and the amorphous glass substrate 150 and improving reliability.

### Third Embodiment

The present embodiment describes a method for manufacturing the LED array substrate 100 shown in the first embodiment and the LED device 110 shown in the second embodiment.

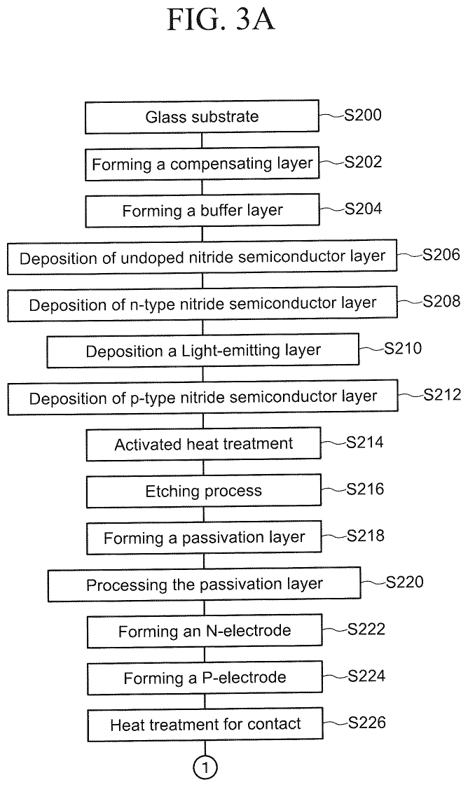

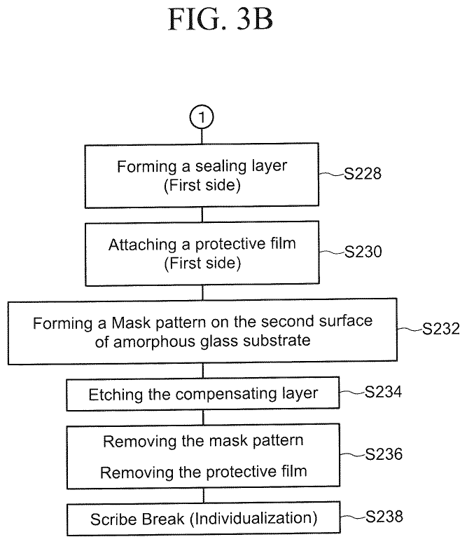

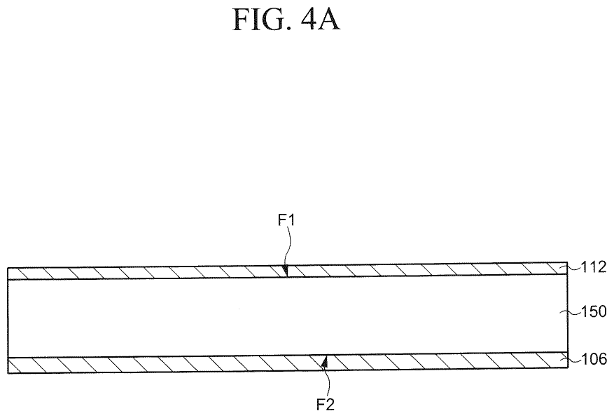

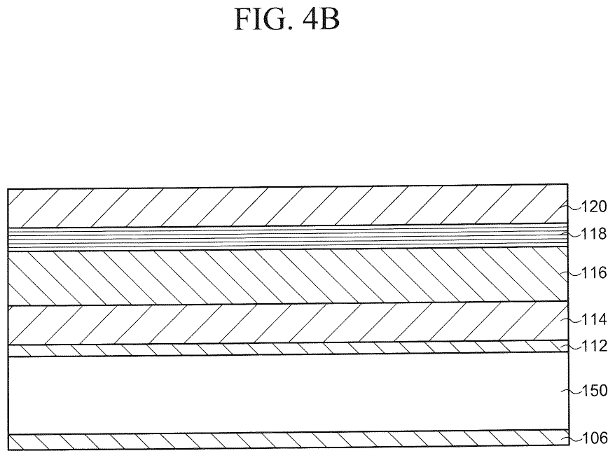

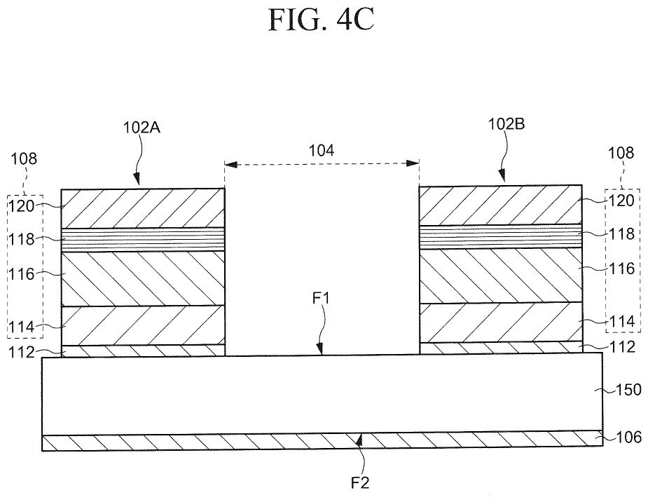

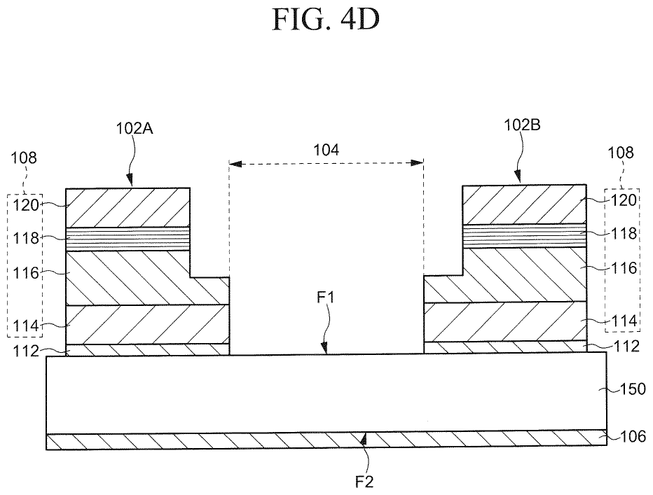

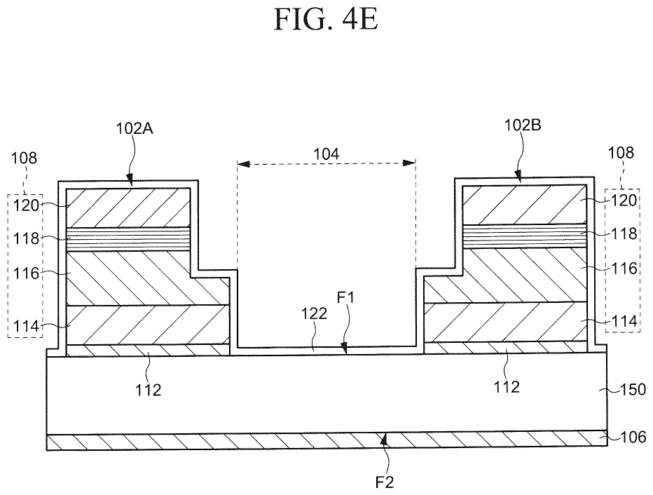

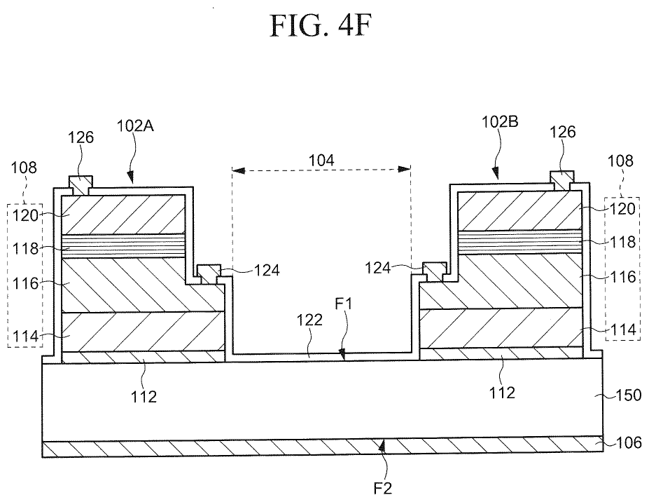

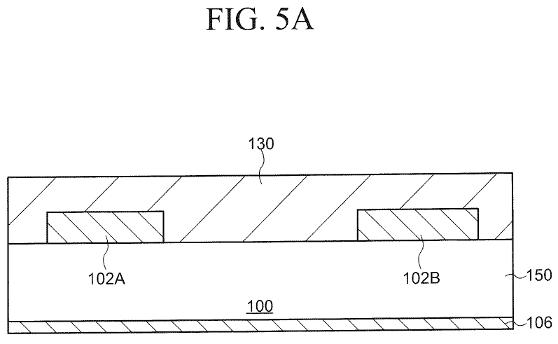

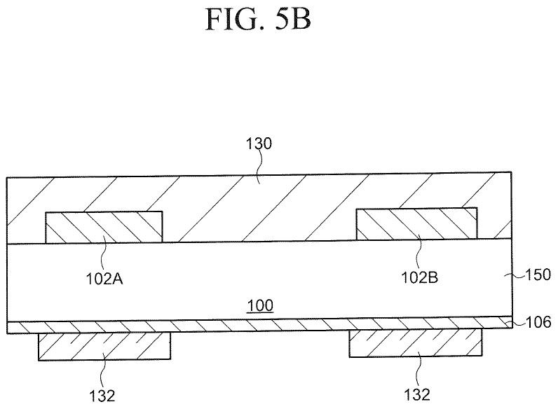

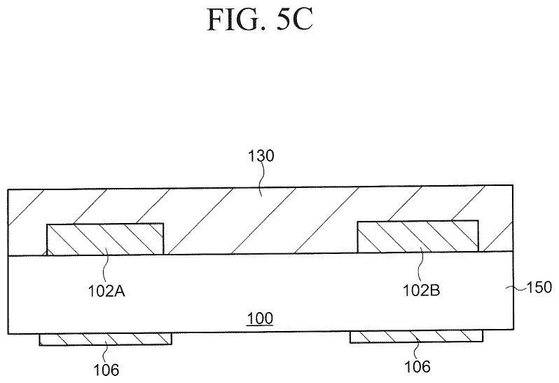

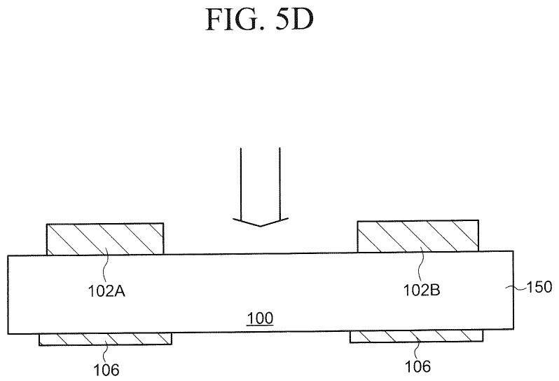

FIG. 3A is a flowchart explaining the manufacturing method of LED devices 110 and shows the process of manufacturing the LED array substrate 100 using a mother glass substrate and individualizing each LED device 110. The following description refers to the flowcharts shown in FIG. 3A and FIG. 3B, and FIG. 4A to FIG. 4F and FIG. 5A to FIG. 5D as appropriate.

First, an amorphous glass substrate 150 is prepared (FIG. 3A: S200), a compensation layer 106 is formed on the second surface F2 (FIG. 3A: S202), and a buffer layer 112 is formed on the first surface F1 (FIG. 3A: S204). FIG. 4A shows a step where the compensation layer 106 is formed on the second surface F2 of the amorphous glass substrate 150 and the buffer layer 112 is formed on the first surface F1.

For example, the compensation layer 106 is formed on the second surface F2 of the amorphous glass substrate 150 and the buffer layer 112 is formed on the first surface F1, using a sputtering method. The compensation layer 106 and the buffer layer 112 are formed from the materials described in the first embodiment. For example, an aluminum nitride film is deposited as the compensation layer 106. For example, an aluminum nitride film is deposited as the buffer layer 112. The aluminum nitride film formed as the buffer layer 112 has crystallinity and is aligned along the c-axis as described in the first embodiment.

Next, an undoped nitride semiconductor layer 114 is formed (FIG. 3A: S206), an n-type nitride semiconductor layer 116 is formed (FIG. 3A: S208), a light-emitting layer 118 is formed (S210), and a p-type nitride semiconductor layer 120 is formed (FIG. 3A: S212). FIG. 4B shows a step where a nitride semiconductor stack is formed on the buffer layer. The undoped nitride semiconductor layer 114, the n-type nitride semiconductor layer 116, the light-emitting layer 118, and the p-type nitride semiconductor layer 120 are formed on the buffer layer 112 in this order by a sputtering method. Specifically, the undoped nitride semiconductor layer 114, the n-type nitride semiconductor layer 116, and the p-type nitride semiconductor layer 120 are formed from a gallium nitride film. The light-emitting layer 118 is formed by alternately stacking gallium nitride films and indium gallium nitride films so as to have a quantum well structure as described in the first embodiment. In this way, the nitride semiconductor stack 108 is formed.

The deposition of gallium nitride films using the sputtering method involves using sintered gallium nitride as the sputtering target, inert gases such as argon (Ar) and krypton (Kr) as sputtering gases, and controlling the substrate temperature during film deposition to between 400° C. and 600° C. A multi-chamber sputtering apparatus is used, with sputtering targets suitable for depositing the undoped nitride semiconductor layer 114, the n-type nitride semiconductor layer 116, the light-emitting layer 118, and the p-type nitride semiconductor layer 120 being installed in each chamber, enabling these layers to be deposited continuously in a vacuum. Since the nitride semiconductor stack 108 is formed on the buffer layer 112, crystal orientation is controlled, and high crystallinity is obtained.

After each layer of the nitride semiconductor layer is deposited, a heat treatment is performed for activation (FIG. 3A: S214). The heat treatment is preferably performed at a temperature of 600° C. to less than 800° C. in a nitrogen atmosphere. This heat treatment activates the impurities for controlling the valence electrons in the n-type nitride semiconductor layer 116 and the p-type nitride semiconductor layer, thereby improving the conductivity.

Next, an etching process is performed to form the LED device region 102 and the scribe region 104 (FIG. 3A: S216). FIG. 4C shows a step where the nitride semiconductor stack 108 and the buffer layer 112 are etched to form the first LED device region 102A, the second LED device region 102B, and the scribe region 104. The first LED device region 102A and the second LED device region 102B may be formed as a rectangle or a polygonal shape with more corners than a rectangle in a plan view. The scribe region 104 is formed to surround the first LED device region 102A and the second LED device region 102B as viewed from above (see FIG. 1A and FIG. 1B). In the etching process, a predetermined resist pattern is formed on the nitride semiconductor stack 108 by photolithography, and then etching is performed using a dry etching apparatus. A chlorine-based etching gas such as Cl₂ is used as the etching gas. Since the buffer layer 112 is thin, it is etched at the same time as the nitride semiconductor stack 108 during this etching process.

FIG. 4D shows a step of forming a contact region for forming an n-electrode. For the n-electrode 124 to form a contact with the n-type nitride semiconductor layer 116, the p-type nitride semiconductor layer 120 and the light-emitting layer 118 are selectively etched so that the n-type nitride semiconductor layer 116 is exposed in the LED device region 102 in a plan view. In this way, the first LED device region 102A and the second LED device region 102B are formed on the first surface F1 of the amorphous glass substrate 150, and the scribe region 104 is formed between the plurality of LED device regions. On the second surface F2 of the amorphous glass substrate 150, the compensation layer 106 remains over the entire surface to prevent warping of the substrate during the process.

Next, a passivation layer 122 is formed (FIG. 3A: S218). FIG. 4E shows a step where the passivation layer 122 is formed on the entire surface of the first surface F1 of the amorphous glass substrate 150 including the LED device region. The passivation layer 122 is formed by sputtering so as to cover the entire surface of the first surface F1 of the amorphous glass substrate 150. The formation of the passivation layer 122 is not limited to the sputtering method and may also be formed by, for example, the CVD method.

Then, the passivation layer 122 is processed (FIG. 3A: S220). FIG. 4F shows a step where the passivation layer 122 is processed and contact holes are formed so that the p-electrode 126 contacts the p-type nitride semiconductor layer 120 and the n-electrode 124 contacts the n-type nitride semiconductor layer 116. The contact holes are formed to expose the upper surface of the n-type nitride semiconductor layer 116 and the upper surface of the p-type nitride semiconductor layer 120 relative to the passivation layer 122. Then, the n-electrode 124 is formed (S222), and the p-electrode 126 is formed (S224). The n-electrode 124 and p-electrode 126 are each formed from the conductive material described in the first embodiment. The conductive material is deposited by sputtering or vacuum evaporation and patterned using photolithography.

As described in the first embodiment, since the conductive material suitable for forming the n-electrode 124 and the conductive material suitable for forming the p-electrode 126 are different, these two types of electrodes are manufactured in separate processes. There is no restriction on the order in which the n-electrode 124 and the p-electrode 126 are manufactured, and the p-electrode 126 may be manufactured first.

After that, a heat treatment is performed to reduce the contact resistance of the n-electrode 124 and the p-electrode 126 (FIG. 3A: S226). At this step, since the compensation layer 106 is formed over the entire surface of the second surface F2 of the amorphous glass substrate 150, warping of the substrate due to heat treatment can be prevented.

Thereafter, an organic sealing layer 128 is formed to cover the first LED device region 102A and the second LED device region 102B, respectively (FIG. 3B: S228). As described in the first embodiment, the organic sealing layer 128 covering the first LED element region 102A and the second LED element region 102B is formed by coating the photosensitive organic resin composition on the first surface F1 of the amorphous glass substrate 150 and then exposing it to light so that it polymerizes and changes (see FIG. 2A). By this treatment, the organic sealing layer 128 is formed in regions corresponding to the first LED device region 102A and the second LED device region 102B as shown in FIG. 4F, and the scribe region 104 is exposed as shown in FIG. 2A.

As a result of the above steps, a structure capable of functioning as the LED device 110 is formed on the amorphous glass substrate 150. Next, the LED device 110 is individualized from the LED array substrate 100.

A protective film 130 is attached to the LED array substrate 100 (FIG. 3B: S230). FIG. 5A shows a step where the protective film 130 covering the first LED device region 102A and the second LED device region 102B is attached to the first surface F1 of the amorphous glass substrate 150.

A mask pattern 132 for etching the compensation layer 106 is formed (FIG. 3B: S232). FIG. 5B shows a step where the mask pattern 132 for patterning the compensation layer 106 is formed on the second surface F2 of the amorphous glass substrate 150. The mask pattern 132 is formed by photolithography. In this process, since the first surface F1 of the amorphous glass substrate 150 is covered with the protective film 130, even when the substrate is handled by an exposure apparatus or the like, it is possible to prevent damage to the first LED device region 102A and the second LED device region 102B.

Next, the compensation layer 106 is etched (FIG. 3B: S234). FIG. 5C shows the step of etching the compensation layer 106. The compensation layer 106 is etched, for example, by dry etching. When an aluminum nitride film is formed as the compensation layer 106, etching can be performed using a chlorine-based gas.

Then, the mask pattern 132 is removed, the protective film 130 is peeled off (FIG. 3B: S236), and the LED devices 110 are individualized by scribing (FIG. 3B: S238). FIG. 5D shows the step of individualizing the LED array substrate 100. Dicing tape may be attached to the second surface F2 of the amorphous glass substrate 150 for the individualization process. As described in the first embodiment, since the compensation layer 106 and the buffer layer 112 are removed in the scribe region 104, defects associated with scribing can be prevented.

When performing laser scribing, heat dissipation can be prevented, and the amorphous glass substrate 150 can be locally heated to perform scribing, thereby preventing the formation of a modified layer and leaving a clean scribed surface. When performing mechanical scribing, a blade can be used to engrave lines on the amorphous glass substrate 150 to enable high-precision cutting.

The LED device 110 shown in FIG. 2B can be manufactured by the above process. According to the method of manufacturing the LED device 110 shown in the present embodiment, it is possible to prevent defects during the individualization process by forming the LED device region 102 and the scribe region 104 on the first surface F1 of the amorphous glass substrate 150, forming the compensation layer 106 on the second surface F2 side, and removing the compensation layer 106 overlapping the scribe region 104 before scribing. It is possible to individualize LED devices 110 of various shapes from the LED array substrate 100.

### Fourth Embodiment

The present embodiment describes an example of a process that can be applied when scribing an LED array substrate 100.

The manufacturing method of the LED device 110 shown in the third embodiment may include an additional step of thinning the scribe region 104 of the amorphous glass substrate 150 before scribing the LED array substrate 100.

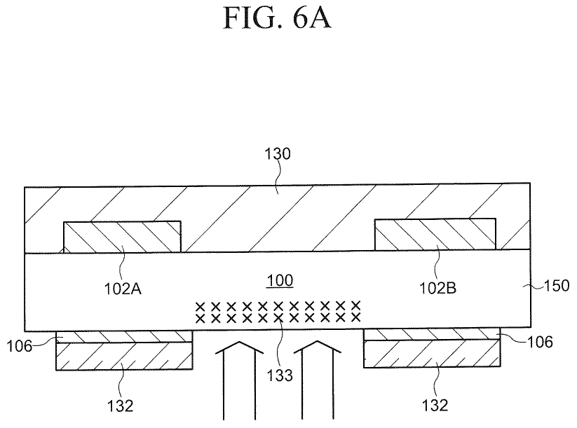

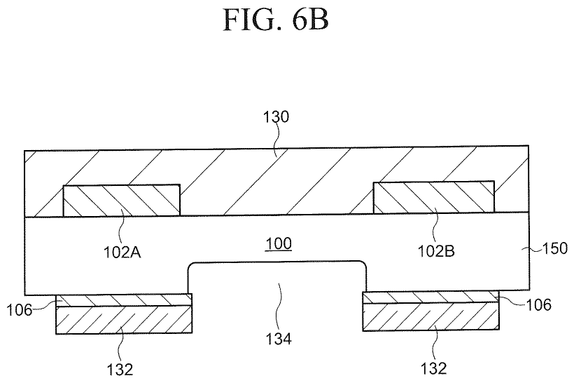

FIG. 6A shows a step where the protective film 130 is disposed on the first surface F1 of the amorphous glass substrate 150, and a laser beam is irradiated from the second surface F2 to form a damaged region 133. The damaged region 133 is formed on the amorphous glass substrate 150 by irradiating a laser beam.

An infrared laser is used to form the damaged region 133. For example, a carbon dioxide laser can be used as an infrared laser. Laser beams pulsed by the laser beam source are focused by an optical system and irradiated onto the amorphous glass substrate 150. At this time, the focal position is set at a position deeper than the surface of the second surface F2 of the amorphous glass substrate 150. Microcracks can be generated inside the amorphous glass substrate 150 by irradiating the laser beam, thereby forming the damage region 133. The depth of the damage region 133 can be adjusted as appropriate depending on the irradiation conditions of the pulsed laser beams. The damage region 133 is a region where the compensation layer 106 is not arranged and is arranged in a region overlapping the scribe region 104.

FIG. 6B shows a step where the second surface F2 of the amorphous glass substrate 150 is etched to form a recess region 134. The recess region 134 is a region where the amorphous glass substrate 150 has been etched to form a thin plate. The amorphous glass substrate 150 can be etched using, for example, an aqueous solution of hydrofluoric acid. The damage region 133 formed on the amorphous glass substrate 150 is a region in which high-density microcracks are formed, and because the density is low, the etching speed in this region is faster than in other regions. Therefore, when the amorphous glass substrate 150 is immersed in an etching solution and etched while the damage region 133 is formed, the amorphous glass substrate 150 can be etched to a predetermined depth without causing damage to the compensation layer 106. At this time, since the protective film 130 is disposed on the first surface F1 side of the amorphous glass substrate 150, it can be protected from immersion in the etchant.

It is possible to reduce the thickness of the amorphous glass substrate 150 in the scribe region 104 to about ¼ to ½ by this treatment. After this treatment, the LED array substrate 100 can be more easily divided by scribing. Both laser scribing and mechanical scribing can be used for scribing.

The processing method of the amorphous glass substrate 150 according to the present embodiment is applicable to fine regions, and therefore, it is applicable even if the scribe region 104 is bent or curved. Therefore, when individualizing the LED device 110 having a complex shape in a plan view, the addition of the process shown in the present embodiment enables easier scribing with higher processing accuracy.

### Fifth Embodiment

The present embodiment shows a configuration of the LED array substrate different from that of the first embodiment.

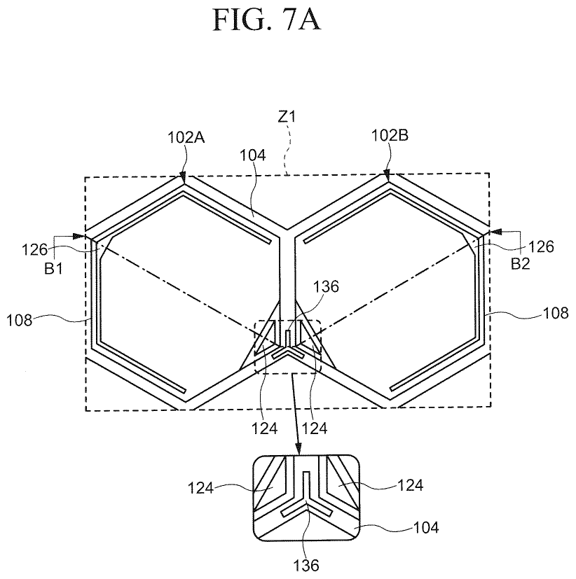

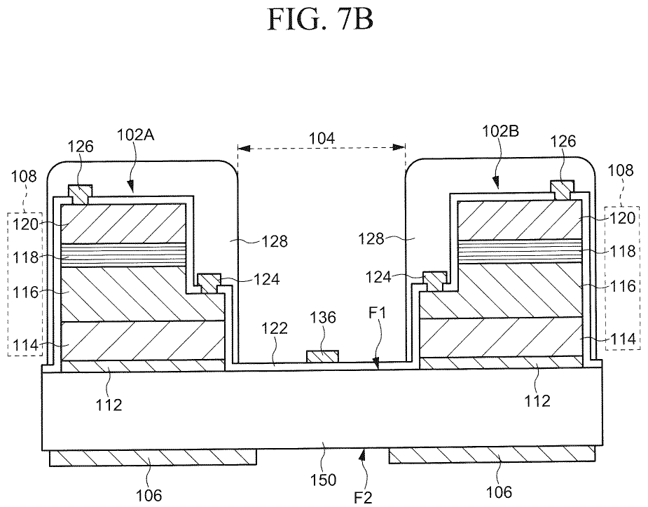

FIG. 7A is a plan view corresponding to a region Z1 shown in FIG. 1A. As shown in FIG. 7A, the LED array substrate 100 according to the present embodiment has an alignment marker 136 formed in the scribe region 104. The alignment marker 136 is used for alignment when scribing.

The alignment marker 136 is arranged outside the LED device region 102. The alignment marker 136 may be arranged at a portion where the scribe region 104 is bent in the region where the LED device region 102 is arranged. The position and direction of the scribing process can be aligned by the alignment marker 136. The shape of the alignment marker 136 is not limited to the shape shown in the figure, and various shapes can be applied.

FIG. 7B shows a cross-sectional structure corresponding to the line B1-B2 shown in FIG. 7A. The alignment marker 136 is formed using a layer that forms the LED device 110. For example, the alignment marker 136 may be formed in a layer that forms the n-electrode 124 or the p-electrode. The alignment marker 136 may be formed with the layer forming the buffer layer 112 or the nitride semiconductor stack 108. The alignment marker 136 is partially arranged in the scribe region 104 and does not affect scribing.

According to the present embodiment, by arranging the alignment marker 136 on the LED array substrate 100, it is possible to accurately control the irradiation position of the laser beam and the position where the blade is applied during scribing, thereby improving processing accuracy.

### Sixth Embodiment

The present embodiment describes the configuration of an LED array substrate different from that of the first embodiment.

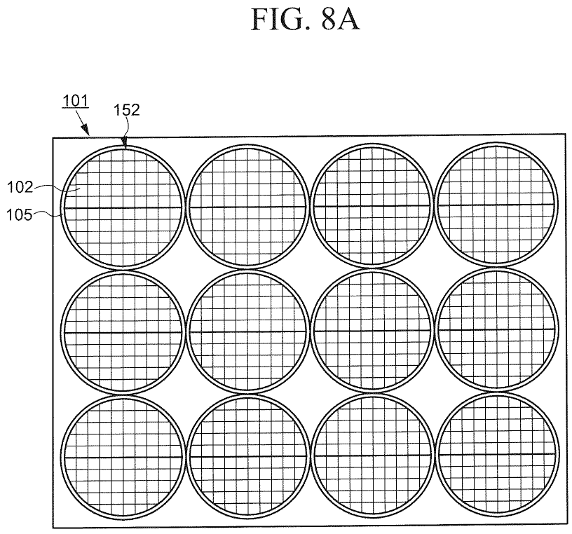

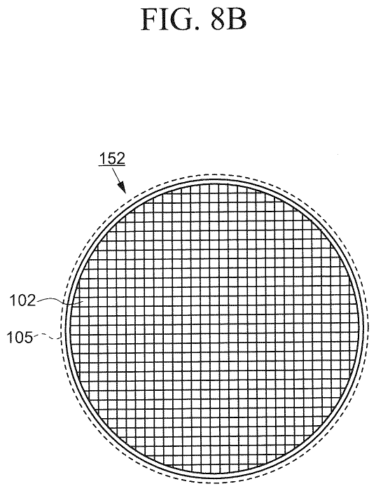

FIG. 8A is a plan view of an LED array substrate 101 according to the present embodiment. A plurality of LED device regions 102 are arranged on the LED array substrate 101. An arc-shaped scribe region 105 is formed on the LED array substrate 101 so as to surround the plurality of LED device regions 102 in an arc.

The size of a circular substrate 152 cut out from the arc-shaped scribe region 105 is from 2 inches to 12 inches. The size of the circular substrate 152 is the same as that of a commercially available sapphire wafer.

FIG. 8B is a plan view of the circular substrate 152 that is cut out by scribing the arc-shaped scribe region 105 formed on the LED array substrate 101. As mentioned above, the size of the circular substrate 152 is from 2 inches to 12 inches, which is the same size as a commercially available sapphire wafer used for manufacturing LEDs.

A plurality of LED device regions 102 are arranged within the circular substrate 152. The circular substrate 152 is cut out from the LED array substrate 101 during the manufacturing process of the LED devices 110. For example, the circular substrate 152 is scribed into a circular shape from the LED array substrate 101 after the passivation layer 122 formation process shown in the third embodiment.

After the circular substrate 152 is cut out, the contact holes are formed, and the n-electrodes 124 and the p-electrodes 126 are formed. Since the circular substrate 152 has the same size as a commercially available sapphire wafer, the subsequent processes can be performed using existing LED device manufacturing equipment.

As shown in FIG. 8A, the LED array substrate 101 includes a plurality of arc-shaped scribe regions 105 for cutting out circular substrates 152. Therefore, a plurality of circular substrates 152 can be manufactured in the same film formation process, thereby improving productivity.

The embodiments described above as embodiments of the present invention may be combined as appropriate, provided that they are not mutually contradictory. Based on each embodiment, the scope of the present invention also includes those in which a person skilled in the art adds, deletes, or redesigns components as appropriate, or adds, omits, or changes conditions of processes, as long as they embody the essence of the present invention.

It should be understood that other advantageous effects different from those described above, which are apparent from the description herein or can be easily predicted by those skilled in the art, are also provided by the present invention.

What is claimed is:

1. An LED device comprising:
an amorphous glass substrate having a first surface and a second surface opposite to the first surface;
a buffer layer arranged on the first surface of the amorphous glass substrate;
a nitride semiconductor stacked structure including an n-type nitride semiconductor layer, a light-emitting layer, and a p-type nitride semiconductor layer on the buffer layer;
a passivation layer covering the nitride semiconductor stacked structure;
an n-electrode in contact with the n-type nitride semiconductor layer, and a p-electrode in contact with the p-type nitride semiconductor layer; and
a compensation layer on the second surface of the amorphous glass substrate,
wherein
a coefficient of thermal expansion of the compensation layer exceeds a coefficient of thermal expansion of the amorphous glass substrate and is less than a coefficient of thermal expansion of a semiconductor layer forming the nitride semiconductor stacked structure,
an end of the buffer layer and an end of the nitride semiconductor stacked structure is inside an end of the amorphous glass substrate, and
the passivation layer extends from the end of the buffer layer and the nitride semiconductor stacked structure to above the first surface of the amorphous glass substrate.

2. The LED device according to claim 1, wherein an end of the compensation layer is located further inwards than the end of the amorphous glass substrate.

3. The LED device according to claim 1, further comprising an organic sealing layer on the passivation layer,
wherein the end of the organic sealing layer is further outwards than the end of the buffer layer and the nitride semiconductor stack and further inwards than the end of the amorphous glass substrate.

4. The LED device according to claim 1, wherein the compensation layer includes one or both of an aluminum oxide layer and an aluminum nitride layer.

5. The LED device according to claim 1, wherein the buffer layer includes one or both of an aluminum oxide and an aluminum nitride.

6. The LED device according to claim 1, wherein the amorphous glass substrate is a polygonal shape having more angles than a square in a plan view.

7. A method for manufacturing LED device, the method comprising:
forming a compensation layer on an amorphous glass substrate, the amorphous glass substrate having a first surface and a second surface opposite the first surface, and the compensation layer being formed on the second surface;
forming a buffer layer on the first surface of the amorphous glass substrate;
forming a nitride semiconductor stack on the buffer layer, the nitride semiconductor stack including an n-type nitride semiconductor layer, a light-emitting layer, and a p-type nitride semiconductor layer;
patterning the nitride semiconductor stack and the buffer layer, forming LED device regions and a scribe region between the LED device regions;
forming a passivation layer covering the LED device regions and the scribe region;
forming openings in the passivation layer overlapping the LED device regions;
forming electrodes overlapping the openings;
forming an organic sealing layer on the passivation layer and the electrodes covering the LED device regions;
attaching a protective film to the first surface of the amorphous glass substrate;
forming an opening region in the compensation layer, the opening region being formed in the region overlapping the scribe region; and
individualizing the LED device regions at the scribe region after removing the protective film.

8. The method according to claim 7, the method further comprising forming an alignment marker in the scribe region using at least one layer selected from the buffer layer, the nitride semiconductor stack, and the electrodes.

9. The method according to claim 7, wherein the compensation layer is formed by one or both of an aluminum oxide layer and an aluminum nitride layer.

10. The method according to claim 7, wherein the buffer layer is formed by one or both of an aluminum oxide layer and an aluminum nitride layer.

11. The method according to claim 7, wherein the organic sealing layer is formed to not overlap the scribe region.

12. The method according to claim 7, wherein the compensation layer is formed of a material having a thermal expansion coefficient greater than that of the amorphous glass substrate and less than that of the semiconductor layer forming the nitride semiconductor stack.

13. The method according to claim 7, wherein the LED device region is formed with a polygonal shape having more corners than a rectangle in a plan view, and the scribe region is formed to surround the region of the polygonal shape.

14. An LED array substrate comprising:
an amorphous glass substrate having a first surface and a second surface opposite to the first surface;
LED device regions arranged in a space separated from the first surface of the amorphous glass substrate;
a scribe region arranged on the first surface in a region separated from the LED device regions;
a passivation layer covering the LED device regions and the scribe region on the first surface; and
a compensation layer on the second surface of the amorphous glass substrate,
wherein
the LED device region includes a buffer layer on the first surface of the amorphous glass substrate, and a nitride semiconductor stack including an n-type nitride semiconductor layer, a light-emitting layer, and a p-type nitride semiconductor layer, and n-electrodes and a p-electrodes,
a thermal expansion coefficient of the compensation layer is greater than a thermal expansion coefficient of the amorphous glass substrate and less than a thermal expansion coefficient of semiconductor layers forming the nitride semiconductor stack,
the passivation layer extends to the scribe region,
the buffer layer, the nitride semiconductor stack, the n-electrode and the p-electrode does not extend into the scribe region, and
the compensation layer includes an opening region overlapping the LED device regions and partially not overlapping the scribe region.

15. The LED array substrate according to claim 14, further comprising an organic sealing layer on the passivation layer,
wherein the organic sealing layer covers the LED device regions and exposes the scribe region.

16. The LED array substrate according to claim 14, wherein an alignment marker is formed in the scribe region with at least one layer selected from the buffer layer, the nitride semiconductor stack, the n-electrode, and the p-electrode.

17. The LED array substrate according to claim 14, wherein the compensation layer includes one or both an aluminum oxide and an aluminum nitride.

18. The LED array substrate according to claim 14, wherein the buffer layer includes one or both of an aluminum oxide and an aluminum nitride.

19. The LED array substrate according to claim 14, wherein the LED device regions are a polygonal shape with more angles than a square in a plan view, and the scribe region surrounds the region of the polygonal shape.
